(19) United States
(12) Patent Application Publication
(10) Pub. No.: US 2011/0303258 A1
(43) Pub. Date: Dec. 15, 2011

(54) SYSTEM FOR RECLAMATION OF WASTE THERMAL ENERGY

(76) Inventor: Jerome KAHN, Hutchinson, KS (US)

(21) Appl. No.: 13/221,264

(22) Filed: Aug. 30, 2011

Related U.S. Application Data
(63) Continuation of application No. 12/253,560, filed on Oct. 17, 2008.
(60) Provisional application No. 60/981,149, filed on Oct. 19, 2007.

(51) Int. Cl. H01L 35/28; H02J 1/10

(52) U.S. Cl. 136/205; 136/224; 307/43

(57) ABSTRACT

A waste heat reclamation device absorbs waste heat from a heat generating object. A thermocouple loop is used to convert thermal energy into electrical energy which may be utilized to provide electrical power to an electronic device that is the heat generating object. The invention increases the efficiency of electronic devices such as computer processing units.

### CROSS-REFERENCE TO RELATED APPLICATION

This application is a continuation of U.S. patent application Ser. No. 12/253,560, filed Oct. 17, 2008, entitled SYSTEM FOR RECLAMATION OF WASTE THERMAL ENERGY, that claims priority to U.S. Provisional Application No. 60/981,149, filed Oct. 19, 2007, the entirety of both of which are incorporated herein by reference.

### STATEMENT REGARDING FEDERALLY SPONSORED RESEARCH OR DEVELOPMENT

n/a

### FIELD OF THE INVENTION

The present invention relates to an apparatus and method for capturing energy from waste heat generated by an electrical system. Specifically, the present invention provides a device for use in conjunction with or in place of a heat sink that absorbs thermal energy radiating from electrical components and converts this heat into useful electrical power.

### BACKGROUND OF THE INVENTION

The two dominant trends in computer processing today are toward reducing physical size and increasing processing speeds. The need for convenience and portability continues to drive electronic designers to smaller and more densely organized circuitry. The need for faster and increasingly complex and simultaneous calculations continues to push the industry toward faster computational speeds and data processing. These trends converge in smaller, denser circuitry that also inherently results in faster processing speeds. Unfortunately, these trends also produce some negative results. Higher processing speed requires greater current demands while size reduction results in greater resistivity in the circuits. These stronger currents, pushing through more resistive circuits, result in the radiation and convection of substantial amounts heat that both wasted and potentially damaging.

Unchecked, this heat can damage and ruin circuits and other components of a central processing unit. Waste heat also significantly affects the cost of operating computer processors. The heat so generated is waste energy. As computers grow and use more energy, more heat is produced and more energy wasted. This problem is compounded by the fact that it takes additional energy to dispose of this waste energy.

It has become well known in the art to use heat sinks to remove waste heat from processors, thereby preventing damage and allowing continued high speed processing. Heat sink are constructed of thermally conductive metals attached to a heat generating processor components and having a series of protruding fins or other structure that facilitates and maximizes rapid heat dissipation. These are often used in conjunction with fans. Liquid cooling has become more common especially with large data processing centers. And more recently, gas expansion coolers and thermoelectric Peltier coolers have been developed for cooling entire processing units as well as local hot spots. Companies have begun developing small chips that convert thermal energy to electricity in order to recover waste heat. Some purport to function at 70-80% of the Carnot cycle theoretical efficiency for heat pumps. In general, utilizing wasted heat has been a focus of research into thermoelectric converters which rely upon the Seebeck effect. Further, organic thermoelectric materials have been discovered.

Although various heat sinks allow continuous high running speeds of computer circuitry by dissipating waste heat, they create problems of their own. The heat sinks themselves take up space and therefore increase the overall size of a computer processing unit. They increase the amount of power a computer processor or system requires to remove the wasted heat. This results in computers that require more energy and therefore become less efficient. Furthermore, the addition of heat sink components further complicates the manufacture of computer processors and adds to their maintenance requirements. That is, as cooling devices become more sophisticated, they also become more complicated and difficult to maintain.

It is therefore desirable to provide a simple, low cost method for dissipating heat from electronic circuitry.

It is also desirable to provide a means for reclaiming waste heat energy from electronic circuitry and It is also desirable to provide a means for increasing the overall efficiency of a computer processor. The instant invention addresses these long felt needs in the art.

### SUMMARY OF THE INVENTION

The present invention provides an apparatus and method for improving the efficiency of electrical devices by reclaiming otherwise wasted heat energy to provide electrical power. Waste thermal energy, i.e., heat generated by data processing and storage centers is harnessed and conditioned into usable electrical energy. This harvested thermal energy is converted into electrical energy which may then be fed into a main power bus of a data processing unit.

The invention overcomes difficulties in the prior art by converting waste heat into electric current that may be recycled for use as a power source for the electronic device the heat is reclaimed from. Potentially damaging waste heat is removed from sensitive electronic circuitry by absorption by a thermocouple device. By reclaiming waste thermal energy using thermocouples, the invention improves the efficiency of electronic devices such as computer processors. The thermocouple device so utilized is preferably small and substantially planar. Therefore, it does not add substantial volume to the overall size of a processing unit to which it is added.

Existing heat sinks remove damaging waste heat by dissipating it into the atmosphere. The present invention removes the waste heat from electrical components by absorbing, harnessing and recycling the thermal energy and converting it to electric power. The electric current generated by the harnessed thermal energy is properly conditioned by the present invention and fed into a power supply or a power supply bus. In this fashion, the present invention both cools electrical systems and increases efficiency. The preferred embodiment of the invention may be retrofitted into existing computer processing or other units and operate in conjunction with existing heat sinks and cooling systems. The invention may not completely eliminate the need for conventional means of managing waste heat. The extent to which conventional waste heat management technologies will still be relied on will depend on the amount of heat generated, the efficiency of the thermocouple device and other factors known in the art.

Preferably, the invention utilizes a thermocouple device either alone or in conjunction with a heat sink. The thermocouple device is placed in thermal contact with a heat-generating component of a processing, storage or other electronic device. Those skilled in the art will appreciate that the Seebeck effect will induce an electric current in a thermocouple that has been put in contact with a heat-generating object. The current generated within the thermocouple may be routed through a power conditioner and used to supply power to an electronic device. Typically, the power conditioner includes a diode OR circuit so that it may be properly conditioned for use as a power source for the processor. Those of skill in the art will appreciate that a diode OR circuit or equivalent device will allow current supplied by the thermocouple to communicate with a power supply to feed a current proportional to the heat absorbed back to the processor. It is preferred to use an apparatus for properly conditioning the current generated by the thermocouple because the generated current will fluctuate, especially when power is initially supplied to the heat generating system.

The invention may alternatively be embedded directly into a heat generating electrical component during fabrication such that the component has a self-contained thermal recovery feature and thus lower overall waste heat output and reduced power consumption.

It is an object of the present invention to provide a means for absorbing waste heat and converting it into usable electrical energy.

There has thus been outlined, rather broadly, the more important features of the invention in order that the detailed description thereof that follows may be better understood, and in order that the present contribution to the art may be better appreciated. There are features of the invention that will be described hereinafter and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

### BRIEF DESCRIPTION OF THE DRAWINGS

A more complete understanding of the present invention, and the attendant advantages and features thereof, will be more readily understood by reference to the following detailed description when considered in conjunction with the accompanying drawings wherein:

FIG. 1 is a flow chart of energy flow through a typical computer processing system incorporating the present invention;

FIG. 2 is an embodiment of the invention;

FIG. 3 is an alternative embodiment of the invention;

FIG. 4 is a typical diode OR circuit of the invention;

FIG. 5 is an alternative embodiment of the invention; and

FIG. 6 is an alternative embodiment.

### DETAILED DESCRIPTION OF THE INVENTION

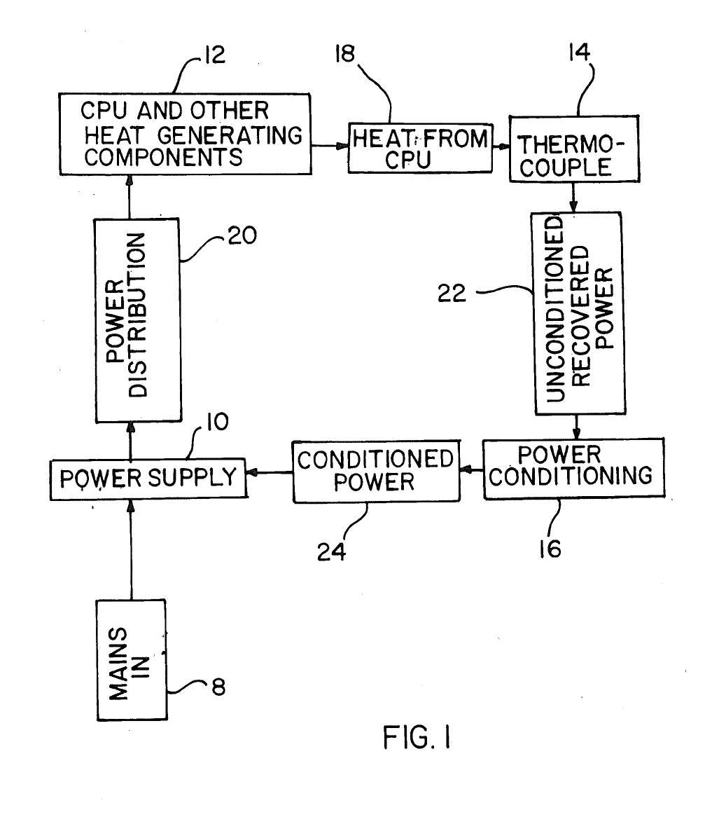

Referring now to the drawings, FIG. 1 shows a flow chart of energy through an electrical computer processor and the invention. Electric power 8 from an outside source is introduced to the processing unit's power supply 10 which is then distributed to various components within a central processor unit 12 by a power distribution bus 20. Those skilled in the art will appreciate that computer processors typically include a power source 10 that conditions an outside power source to provide appropriate current for various components of the central processing unit (CPU) 12. Those of skill in the art will appreciate that a power supply 10 is typically connected to the central processing unit 12 by a power supply bus 20 that distributes the electric current from power supply 10 to various and sundry electrical components of the central processing unit 12.

Many of the components of CPU 12 will generate a substantial amount of waste heat 18 as current passes through them. This heat 18 is usually conducted to a heat sink which is generally comprised of a metal plate having thermal conductivity and a distinct geometry. This highly conductive metal plate removes a substantial amount of waste heat from various components of the CPU 12. A series of fins extend outwardly from the heat sink increasing surface area and thereby facilitating more rapid dissipation of excess heat into the ambient air. Heat may also be removed from the heat sink by other devices such as, but not limited to, heat pipes, liquid cooling systems, air cooling systems, Peltier coolers, gas expansion coolers, electric coolers and the like.

In the instant invention, waste heat 18 is transferred, typically through a heat sink, to a waste heat harnessing device 14. In this particular embodiment, waste heat harnessing device 14 comprises a thermocouple. When heat is applied to one side of the thermocouple, a heat gradient is formed across it thereby inducing an electric current. This electric current 22 may be readily transferred to a power conditioner 16. Current 22 arrives at power conditioner 16 fluctuating and unsteady. Power conditioner 16 conditions the recaptured current 22 into a constant, steady current and a desired voltage. The now conditioned current 24 is fed back into the power supply 10. Those skilled in the art will appreciated that conditioned, reclaimed energy 24 may similarly be fed to the main power bus 20 or directly to one of the components of CPU 12.

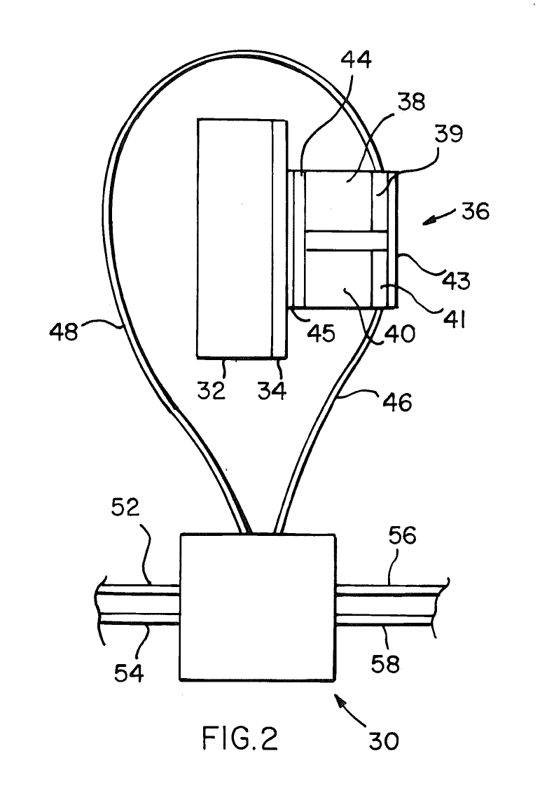

FIG. 2 shows a waste heat reclamation system of the present invention of FIG. 1. The waste heat reclamation system comprises a waste heat harnessing device 36 and a current condition device 30. Device 36 is in thermal contact with a heat generating electrical means 32. Those of skill in the art will appreciate that a wide variety of objects, electrical and otherwise, generate excess heat. If this heat is not removed, it may damage, destroy, or reduce the efficiency of a heat generating means 32, as well as other components proximal to the heat generating means 32 which may include any of a wide variety of electrical components, including, but not limited to, an integrated circuit, a microprocessor, a semiconductor, an electric motor, a memory storage device, an electrical or computing bus, combinations thereof and the like.

Heat generating means 32 is in thermal communication with heat sink 34. It preferably is substantially planar and comprised of a thermally conductive material such as a metal including copper, aluminum or the like. Heat sink 34 is preferably secured to heat generating component 32 by a thermally conductive epoxy resin or other adhesive. It may alternatively be attached by mechanical or other means, so long as it is in thermally conductive contact.

The waste heat harnessing device 36 in this embodiment is a typical thermocouple, well known in the art. Thermocouple 36 includes a thermocouple loop having a first conductor 38 and a second conductor 40. Junction 44 is an electrically conductive material in contact with conductors 38 and 40. Junction 44 is also attached to heat sink 34 by a thermally conducive and electronically insulating layer 45. Those skilled in the art will appreciate that it is preferable that the only portion of thermocouple 36 in electrically conductive contact with any object are leads 39 and 41 which are attached to conducting wires 48 and 46 respectively. Any objects in electrically conductive contact with thermocouple 36 other than conducting wires 48 and 46 may decrease the current transferred to conditioner 30, thereby decreasing the efficiency of the waste heat reclamation device 30. Electrically insulating layer 43 covers leads 39 and 41.

As the waste heat generating component 32 is actuated, heat is created and transferred from it into heat sink 34. Waste heat is then transferred through electrically insulating, thermally conductive layer 45 into junction 44. This creates a temperature differential between junction 44 and leads 39 and 41. Because conductors 38 and 40 are comprised of different conducting material, the heat differential induces the Seebeck effect in the thermocouple 36. This results in an electric current flowing through leads 39 and 41 into conducting wires 48 and 46 respectively. The current induced in the thermocouple 36 is transferred to the energy conditioner 30 by wires 46 and 48. Conditioner 30 is fed a current from a power source (not shown) by wires 52 and 54. The variable current supplied by thermocouple 36 to the conditioner 30 is combined with a variable amount of power from wires 52 and 54 such that it may provide a stable, continuous, output current through output wires 56 and 58. The output current generated by conditioner 30 may be used to supply power to a power bus within a computer processing unit or any other suitable component.

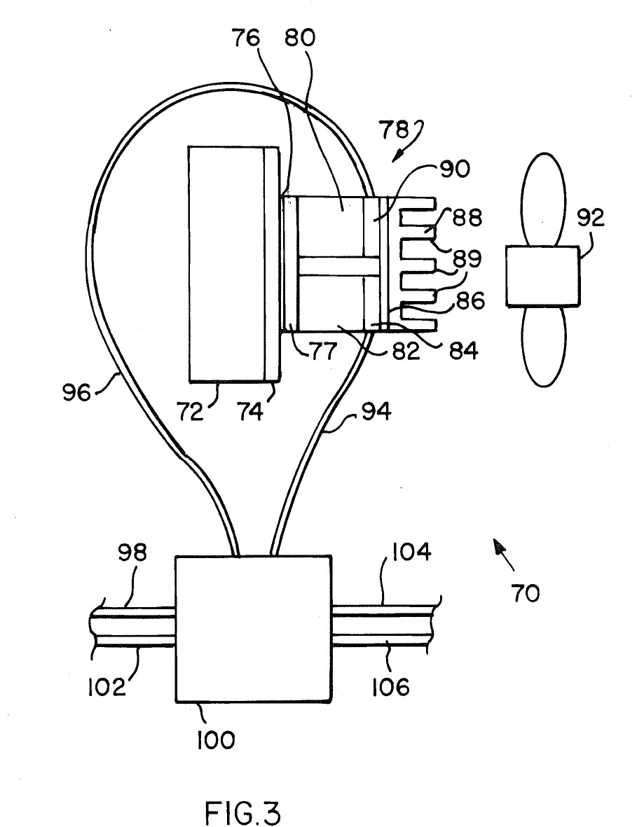

FIG. 3 shows a second embodiment of the invention that maximizes the heat differential within the thermocouple 78. Waste heat reclamation device 70 thereof includes a thermocouple 78 and a conditioning unit 100. Thermocouple 78 has a first conductor 80 and a second conductor 82 joined by junction 77. As with the embodiment of FIG. 2, junction 77 is bound to heat sink 74 by a thermally conductive but electrically insulating layer 76. Heat sink 74 is thermally conductively attached to waste heat generating component 72. Leads 84 and 90 connect thermocouple 78 to conducting wires 94 and 96 to conduct a current to conditioning unit 100. The current so supplied to conditioning unit 100 by thermocouple 78, through conducting wires 96 and 94, is conditioned to provide a constant current to outputs lines 104 and 106. Power Lines 98 and 102 provide additional power to conditioning unit 100 as needed to convert the varying current supply by thermocouple 78 into a more stable, steady current.

Thermocouple 78 has an outer insulating layer 86. Heat sink 88 is thermally conductively attached to electrically insulating and thermally conductive layer 86. Heat sink 88 exhibits a plurality of fins 89 that facilitate dissipation of heat. Fan 92 works in conjunction with heat sink 88 by blowing air across fins 89 to effect cooling by convection.

As heat is continuously transferred from component 72 through heat sink 74 and into junction 77 of thermocouple 78, heat will gradually move through conductors 80 and 82 and gradually reduce the heat differential across the thermocouple. This in turn reduces the current generated by thermocouple 78 and fed into conditioning unit 100. Heat sink 88 and fan 92 help to maintain an optional temperature differential across thermocouple 78. The embodiments shown in FIG. 2 and FIG. 3 may be readily incorporated into existing CPUs by simply retrofitting existing heat sinks.

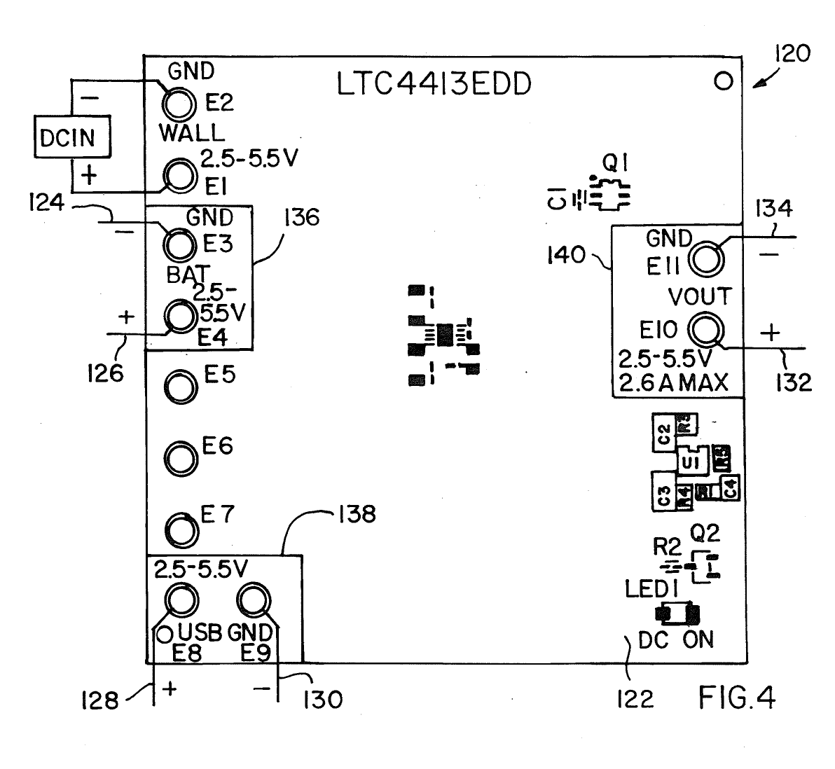

FIG. 4 shows a third embodiment in the form of a typical conduction unit 120 for use in the invention. Conduction unit 120 is comprised of a diode OR 122. A suitable such diode is made by Linear Technology Corp and sold as chip LTC 4412. A power supply is fed into input 136 of diode OR 122 through conducting wires 126 and 124. Diode OR 122 is also connected to a thermocouple waste heat reclamation device by means of conducting wires 128 and 130 at input 138. Diode OR 122 supplies a constant, steady current to wires 132 and 134 at output 140 so long as current is provided at least from the power source feeding input 136. As current is fed into diode OR 122 through input 138, the amount of current the diode OR 122 accepts through input 136 decreases accordingly. The current provided through output 140 is always equal to the sum of the inputs received from inputs 136 and 138. In this fashion, conditioning unit 120 maintains a constant and stable output current strength.

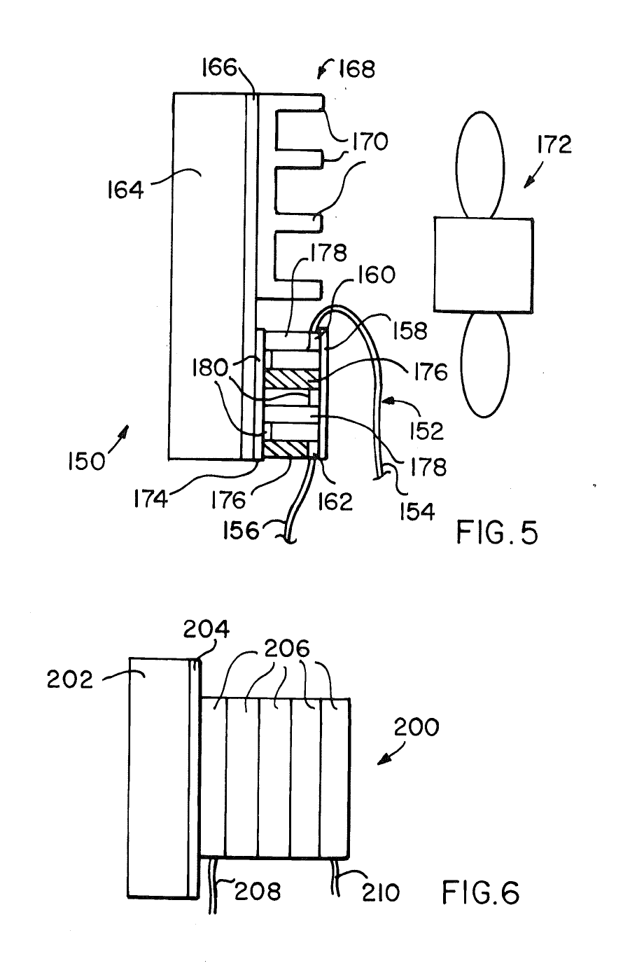

FIG. 5 shows a fourth embodiment of a waste heat harnessing device 150 of the present invention. In this embodiment, waste heat harnessing device 152 is a thermocouple device having a series of thermocouples within it. This is a relatively common configuration for thermocouple devices. It is well know in the art to combine two or more thermocouples into a series of many thermocouples in much the same way the electric batteries are placed in series. Heat harnessing device 152 is attached by means of thermally conductive electrically insulating layer 174 to heat sink 166 which is attached to waste heat generating device 164. Heat sink 166 is also attached in a thermally conductive way to heat dissipating device 168 having a plurality of fins 170. There exist many heat sinks which themselves have a series of fins extending outwardly from them instead of a separate heat dissipating device attached to it. Fan 172 in this embodiment aids in the dissipating of heat through fins 170 and also helps to maintain the maximum thermal differential within the heat harnessing device 152. Conducting wires 154 and 156 are attached to leads 160 and 162 within the heat harnessing device to carry current through a conditioning unit not shown. The heat harnessing device 152 includes an exterior thermally conductive layer 158 that acts as a heat sink. Alternating columns of conducting materials 178 and 176 are connected by junctions 180 to produce a thermocouple series. As heat is transferred from object 154 through heat sink 166 to the heat harnessing device 152, the Seebeck effect generates a current through device 152 and into conducting wires 154 and 156. FIG. 5 illustrates that the present invention may not only be readily retrofitted through existing heat generating components but may be used in combination with existing methods of dissipating waste heat.

FIG. 6 shows a fifth embodiment, namely a of the heat harnessing device 200. Device 200 is attached to heat sink 204 which is attached to heat generating device 202. Heat harnessing device 200 comprises several thermocouple series devices 206 stacked together. Each thermocouple device 206 consists of a series of thermocouples connected horizontally similarity to the device 152 shown in FIG. 5. By stacking several of these thermocouple series devices 206 into one large thermocouple pile, more heat energy may be harnessed and converted into electric current by harnessing device 200. The current generated is then carried through a conditioning unit, not shown through wires 208 and 210.

FIGS. 5 and 6 illustrate that a variety of thermocouple geometries may be utilized to harness wasted heat energy from various heat generating devices. Which geometry is most applicable depends on the amount of heat generated, the available surface area available for attachment of the harnessing device, the volumetric space surrounding the heat generating device, and various other factors appreciated by those of skill in the art.

Whereas, the present invention has been described in relation to the drawings attached hereto, it should be understood that other and further modifications, apart from those shown or suggested herein, may be made within the spirit and scope of this invention. Descriptions of the embodiments shown in the drawings should not be construed as limiting or defining the ordinary and plain meanings of the terms of the claims unless such is explicitly indicated.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope and spirit of the invention, which is limited only by the following claims.

What is claimed is:

1. A waste heat reclamation system, the system comprising:
a waste heat harnessing device that converts thermal energy into a variable electric current; and
a current conditioning device coupled to the waste heat harnessing device, the current conditioned device conditions the variable electric current into a substantially constant electric current and generates a particular voltage based on conditioned electric current.

2. The waste heat reclamation system of claim 1, wherein the waste heat harnessing device is a solid state device having no moving parts.

3. The waste heat reclamation system of claim 1, wherein the waste heat harnessing device includes at least one thermocouple, the at least one thermocouple generating the variable electric current based on the thermal energy.

4. The waste heat reclamation system of claim 3, wherein the at least one thermocouple is at least one Seebeck thermocouple that converts the thermal energy into the variable electric current based on a Seebeck effect.

5. The waste heat reclamation system of claim 1, further comprising:
a power supply having a power supply current; and
a diode-OR circuit coupled to the power supply, the diode-OR circuit having an output current with a substantially constant strength based at least on the power supply current.

6. The waste heat reclamation system of claim 5, wherein the diode-OR circuit is coupled to the current conditioning device, the diode-OR circuit combines the conditioned electric current with the power supply current such that the output current is based on both the conditioned electric current and the power supply current.

7. The waste heat reclamation system of claim 6, wherein the diode-OR circuit decreases the amount of current accepted from the power supply when the conditioned electric current increases.

8. The waste heat reclamation system of claim 7, wherein the diode-OR circuit increases the amount of current accepted from the power supply when the conditioned electric current decreases.

9. A waste heat reclamation device, the device comprising:
a plurality of thermocouples, each thermocouple converts thermal energy into an electric current; and
at least one current conditioner coupled to the plurality of thermocouples, the at least one current conditioner conditioning the electric current from the plurality of thermocouples into a substantially constant electric current.

10. The waste heat reclamation device of claim 9, wherein the plurality of thermocouples are Seebeck thermocouples that convert the thermal energy into the electric current based on a Seebeck effect.

11. The waste reclamation device of claim 10, further comprising a diode-OR circuit.

12. The waste heat reclamation device of claim 11, wherein the diode-OR circuit combines the conditioned electric current with a power supply current.

13. The waste heat reclamation device of claim 12, wherein the diode-OR circuit decreases the amount of power supply current that is combined with the conditioned electric current when the conditioned electric current increases.

14. The waste heat reclamation device of claim 13, wherein the diode-OR circuit increases the amount of power supply current that is combined with the conditioned electric current when the conditioned electric current decreases.

15. A method for reclaiming waste heat, the method comprising:
harnessing thermal energy from a waste heat generator;
converting the thermal energy into an electric current;
conditioning the electric current to have a substantially constant current; and
generating a particular voltage based on the conditioned electric current.

16. The method of claim 15, further comprising feeding the conditioned electric current to a diode-OR circuit.

17. The method of claim 16, further comprising combining the conditioned electric current with a power supply current.

18. The method of claim 15, further comprising decreasing the amount of power supply current that is combined with the conditioned electric current when the conditioned electric current increases.

19. The method of claim 15, further comprising increasing the amount of power supply current that is combined with the conditioned electric current when the conditioned electric current decreases.

20. The method of claim 15, wherein the converting is based on a Seebeck effect.
